(19) United States
(12) Patent Application Publication
(10) Pub. No.: US 2024/0415032 A1
(43) Pub. Date: Dec. 12, 2024

(54) PHASE CHANGE MEMORY CELL

(71) Applicant: International Business Machines Corporation, Armonk, NY (US)

(72) Inventors: Kangguo Cheng, Schenectady, NY (US); Juntao Li, Cohoes, NY (US); Ruilong Xie, Niskayuna, NY (US); Julien Frougier, Albany, NY (US)

(21) Appl. No.: 18/332,793

(22) Filed: Jun. 12, 2023

(51) Int. Cl. H10N 70/00; H10B 63/10; H10N 70/20

(52) U.S. Cl. CPC H10N 70/8413; H10B 63/10; H10N 70/063; H10N 70/231

(57) ABSTRACT

A phase change memory cell includes a portion of a phase change material over a bi-layer heater where the bi-layer heater has a wider bottom portion on a bottom electrode and a narrower top portion of the bi-layer heater under the phase change material. A first dielectric material is inside and directly contacting the bi-layer heater. The first dielectric material surrounds an air gap in the bottom portion of the first dielectric material. The air gap is adjacent to the wider bottom portion of the bi-layer heater. The narrower top portion of the bi-layer heater is between a sidewall of the first dielectric material and a fourth dielectric material. The fourth dielectric material is above a surface of the bottom portion of the bi-layer heater and contacts a sidewall of a third dielectric material. The phase change memory cell includes a top electrode contacting the phase change material.

### BACKGROUND

The present invention relates generally to the field of semiconductor device technology and more particularly to a phase change memory cell using a bi-layer heater with an air gap in a bottom portion of the bi-layer heater.

Phase change materials include various chalcogenide glass materials that can be used in semiconductor device applications, such as phase change random access memory (PCRAM), which may also be known as PRAM, PCM, or PCME devices. A PCRAM typically has at least two solid phases, a crystalline state, and an amorphous state. The transformation between these two phases can be achieved by changing the temperature of the phase change material. Typically, the transformation of the phase change material can be induced by heating through optical pulses or electrical or Joule heating.

The optical and electronic properties can vary significantly between the amorphous and crystalline phases of the phase change material. In typical memory applications, switching from the high-resistance or “reset” state, where part or all of the phase change material is amorphous, occurs when a current pulse is applied that heats the amorphous material above the crystallization temperature for a sufficiently long time for the material to crystallize. The switch occurs because the threshold switching effect leads to a drastic and sudden (within nanoseconds) reduction of the resistance of the amorphous phase when a certain threshold field is surpassed, at a given threshold voltage. Switching from the low-resistance or “set” state, where the material is crystalline, is achieved by a high current pulse with a very short trailing edge. In typical PCM semiconductor applications, the current pulse heats the material by Joule heating, melts it, and enables very fast cooling (melt-quenching) such that the phase change material solidifies in the amorphous state.

The phase change material exhibits different electrical characteristics depending on its state. In the amorphous state, the phase change material exhibits a higher resistivity than in the crystalline state. A phase change material, in a semiconductor application, may switch between numerous electrically detectable conditions of varying resistivities within a nanosecond time scale with the input of picojoules of energy. Since a phase change material permits reversible phase transformation in a typical case of a phase change random access memory device, the memory bit status can be distinguished by determining the state of phase change material in the memory bit.

### SUMMARY

Embodiments of the present invention provide a semiconductor structure for a phase change memory cell. The semiconductor structure includes a phase change material contacting a top portion of a bi-layer heater. The bi-layer heater has a wider bottom portion contacting a bottom electrode and a narrower top portion of the bi-layer heater contacting the phase change material. The semiconductor structure includes a first dielectric material directly contacting an inside surface of the bi-layer heater. The first dielectric material surrounds an air gap in the bottom portion of the first dielectric material inside the wider bottom portion of the bi-layer heater. The semiconductor structure of the phase change memory cell includes a top electrode above and contacting the phase change material.

Embodiments of the present invention provide a second dielectric material on a portion of the bottom electrode and contacting a sidewall of the wider bottom portion of the bi-layer heater. A third dielectric is on the second dielectric material directly contacting a sidewall of a fourth dielectric material. Embodiments of the present invention disclose the fourth dielectric material directly contacts the sidewall of the narrower top portion of the bi-layer heater and the sidewall of the third dielectric material. The bottom surface of the fourth dielectric material is directly above and contacting the top surface of the wider bottom portion of the bi-layer heater.

Embodiments of the present invention provide the semiconductor structure where the phase change memory material contacts the narrower top portion of the bi-layer heater, the first dielectric material inside the bi-layer heater, the second dielectric material, and the fourth dielectric material. Embodiments of the present invention also include the semiconductor structure where the phase change memory material contacts the narrower top portion of the bi-layer heater, the first dielectric material, and the fourth dielectric material. The narrower top portion of the bi-layer heater is between the fourth dielectric material and the first dielectric material. The bottom portion of the bi-layer heater surrounds the first dielectric material and the air gap inside the first dielectric material.

### BRIEF DESCRIPTION OF THE DRAWINGS

The aspects, features, and advantages of various embodiments of the present invention will be more apparent from the following description taken in conjunction with the accompanying drawings.

FIG. 1 is a cross-sectional view of a semiconductor structure after forming a bottom electrode in a first dielectric material in accordance with an embodiment of the present invention.

FIG. 2 is a cross-sectional view of the semiconductor structure after depositing a second dielectric material and a third dielectric material over the bottom electrode and the first dielectric material in accordance with an embodiment of the present invention.

FIG. 3 is a cross-sectional view of the semiconductor structure after patterning a mask to form a via hole through the second and third dielectric materials in accordance with an embodiment of the present invention.

FIG. 4 is a cross-sectional view of the semiconductor structure after selectively depositing a fourth dielectric material on the exposed surfaces of the third dielectric material in accordance with an embodiment of the present invention.

FIG. 5 is a cross-sectional view of the semiconductor structure after forming a portion of a heater element by conformally depositing a first heater material and conformally depositing a second heater material over the first heater material in accordance with an embodiment of the present invention.

FIG. 6 is a cross-sectional view of the semiconductor structure after conformally depositing a resistive dielectric material to pinch off the via hole in accordance with an embodiment of the present invention.

FIG. 7 is a cross-sectional view of the semiconductor structure after a chemical mechanical polish (CMP) removes horizontal portions of the resistive dielectric material, the first heater material, and the second heater material in accordance with an embodiment of the present invention.

FIG. 8 is a cross-sectional view of the semiconductor structure after an optional CMP removes the horizontal portions of selective dielectric material in accordance with an embodiment of the present invention.

FIG. 9 is a cross-sectional view of the semiconductor structure after depositing a layer of a phase change material over the top surface of the semiconductor structure depicted in FIG. 8, depositing a layer of electrode material over the phase change material, and etching the phase change material and electrode material in accordance with an embodiment of the present invention.

FIG. 10 is a cross-sectional view of the semiconductor structure after depositing a layer of a phase change material over the top surface of the semiconductor structure depicted in FIG. 7, depositing a layer of electrode material over the phase change material, and etching the phase change material and electrode material in accordance with an embodiment of the present invention.

### DETAILED DESCRIPTION

Embodiments of the present invention recognize that a heater element of a phase change memory cell in a semiconductor device utilizing phase change materials is an important element for both memory device applications as well as for applications in analog computing and artificial intelligence (AI) applications. The heater element provides the ability to effectively switch the phase change material from an amorphous state with high resistivity to an electrically conductive crystalline state when a phase transition temperature, such as the melting point of the phase change material is attained. Embodiments of the present invention recognize that in an analog synapse application, the analog state and the dynamic range depend on the heater element to affect changes in the phase change material for efficient semiconductor device function. Embodiments of the present invention recognize that a need to improve the rate of heating and cooling of the heater element and the phase change material would be needed to improve analog synapse device and memory application device functionality.

Embodiments of the present invention recognize that a challenge in utilizing phase change memory devices is the programming current required to switch states of the phase change material. In particular, providing an adequate reset current is proving challenging. Embodiments of the present invention recognize that the ability of a heater element to more quickly and more efficiently provide a thermal energy transfer to the phase change material for a faster state change in the phase change material is desirable. Embodiments of the present invention recognize that an ability to quickly create a phase transition in a mushroom-shaped portion of the phase change material using improved heater element structures would provide improved functionality to semiconductor devices, and in particular, for AI applications and analog device dynamic range improvements for use in deep neural networks.

Embodiments of the present invention recognize that conventional methods of heater formation include filling a small hole in a dielectric material with the heater material that is typically deposited by atomic layer deposition or chemical vapor deposition into the small hole to form the heater. The conventional method of hole formation creates a uniform diameter heater or a tapered heater with a larger top heater diameter where the PCM to heater contact occurs and a smaller bottom heater diameter at the bottom electrode. Embodiments of the present invention recognize that heater elements providing better heat transfer to reduce the reset current and improve the speed of material change of state transitions of the phase change material would be desirable.

Embodiments of the present invention provide a method to form a heater element with a smaller top contact area with the phase change material provides better heat transfer to reduce the reset current and improve the speed of material change of state transitions of the phase change material. The heater element disclosed in embodiments of the present invention with a smaller top contact area with the phase change material can be composed of two layers of heater materials such as a layer of TiN over a layer of TaN. The two layers of the two different heater material form a bi-layer heater element.

Embodiments of the present invention provide the ability to heat-up and quench the mushroom-shaped phase transition area of the phase change material more efficiently and uniformly by providing a ring of the heater material around a dielectric material. The ring or rectangular-shaped ring of the bi-layer heater that is around a dielectric material such as SiN creates a small contact area between the surfaces of the bi-layer heater element and the phase change material.

The first dielectric material resides on a bottom electrode and a portion of an interlayer dielectric material that surrounds the bottom electrode. The second dielectric material resides on the first dielectric material. The first and second dielectric material have a different affinity to the third dielectric material. The second dielectric material deposited on the first dielectric material provides a surface for the selective deposition of a third dielectric material on the second dielectric material. The third dielectric material does not deposit on the first dielectric material.

The third dielectric material selectively deposits on the second dielectric material. The selective deposition of the third dielectric material on the sidewall of the second dielectric material narrows the opening of the cavity or a via hole formed in the first and second dielectric material. The selective deposition of the third dielectric in the via hole or cavity narrows the top portion of the via hole. After deposition of a layer of a first heater material and the second heater material in the via hole, the narrower top portion of the via hole adjacent to the sidewall of the third dielectric material creates a neck for the bottle-shaped bi-layer heater. The two layers of the bi-layer heater are conformally deposited in the via hole or cavity without closing the opening of the via hole. Embodiments of the present invention provide a bi-layer heater where the first layer of the bi-layer heater has a lower thermal conductivity.

Embodiments of the present invention include conformally depositing another or fourth dielectric material which may be a resistive dielectric material on inside surfaces of the bi-layer heater. The fourth resistive dielectric material pinches off or closes the narrower top portion of the via hole. After depositing a layer of phase change material on the exposed top surfaces of the second dielectric material, the fourth resistive dielectric material that is inside the bi-layer heater, only a thin ring and small ring of the bi-layer heater around the fourth resistive dielectric material contacts the phase change material.

Embodiments of the present invention provide the bi-layer heater that surrounds a dielectric material such as a resistive dielectric material. The bi-layer heater forms a ring with a relatively small surface area after one or more planarization process remove horizontal portions of the bi-layer heater, the center dielectric material, and, in some embodiments, the horizontal portions of the selective dielectric material that narrows the top portion of the recess or via hole. Additionally, after conformally depositing the dielectric material inside the bi-layer heater material, an air gap providing good thermal insulation is inside the wider, bottom portion of the bi-layer heater in embodiments of the present invention. Providing a layer of a dielectric material inside the bi-layer heater creates a smaller phase transition region of the phase change material to be melted or quenched, thus enabling more efficient and faster phase changes in the phase change material that uses less power to initiate the phase transitions in the PCM.

Additionally, embodiments of the present invention provide a bottle-like shape of the bi-layer heater element with a layer of the fourth resistive dielectric material inside the bi-layer heater. The wider bottom portion of the bi-layer heater element that is surrounded by the fourth resistive dielectric material on inside surfaces includes an air gap captured within a central bottom portion of the fourth resistive dielectric material. The bottle-like shape of the bi-layer heater with a wider bottom with an air gap adjacent to the center portion of the wider bottom of the bi-layer heater. The narrower, neck area of the bottle-like shaped bi-layer heater in the top portion of the bi-layer heater contacting the phase change material creates the heater hot spot that is close to the heater/phase change material interface. Creating the bi-layer heater hot spot adjacent to the i-layer heater/phase change material interface provides better heat transfer. Providing the heater hot spot adjacent to the bi-layer heater/phase change material interface provides a shorter heat path from the heater hot spot to the phase change material to improve the phase change memory cell performance by reducing the reset current needed to transition the phase change material. Improving the thermal path from the bi-layer heater to the phase change material reduces the amount of heater energy needed to create a phase change in the phase change material thereby improving the performance of the phase change memory device.

Detailed embodiments of the claimed structures and methods are disclosed herein. The method described below does not form a complete process flow for manufacturing integrated circuits, such as semiconductor devices. The present embodiments can be practiced in conjunction with the integrated circuit fabrication techniques currently used in the art, for semiconductor devices, and only so many of the commonly practiced process steps are included as are necessary for an understanding of the described embodiments. The figures represent cross-section portions of a heater element embedded in a PCM material in a semiconductor device, such as a memory device or an analog device. The PCM memory cell disclosed hereinafter may be formed in a middle-of-line semiconductor chip layer or a back-end-of-line layer of the semiconductor chip. The figures are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

In the interest of not obscuring the presentation of the embodiments of the present invention, in the following detailed description, some of the processing steps, materials, or operations that are known in the art may have been combined together for presentation and illustration purposes and in some instances may not have been described in detail. Additionally, for brevity and maintaining a focus on distinctive features of elements of the present invention, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

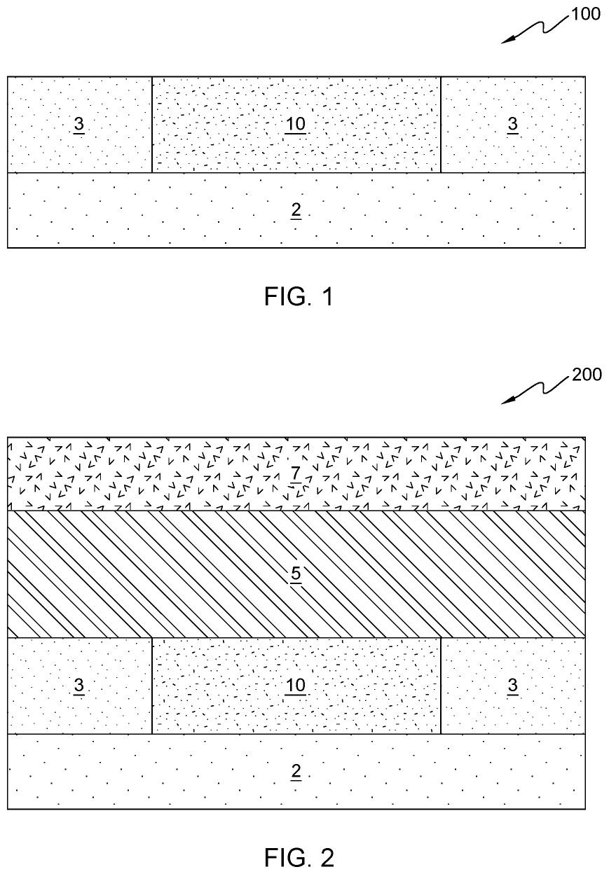

FIG. 1 is a cross-sectional view of semiconductor structure 100 after forming bottom electrode (BE) 10 in dielectric 3 in accordance with an embodiment of the present invention. As depicted, FIG. 1 includes substrate 2, BE 10, and dielectric 3.

Semiconductor substrate 2 may be composed of any semiconductor material used in semiconductor devices such as memory devices. For example, semiconductor substrate 2 may be a semiconductor substrate or wafer including composed of, but not limited to, silicon, silicon germanium, a group IV semiconductor material, a group III-V semiconductor material, a group II-VI semiconductor material, a silicon on insulator (SOI), or other known semiconductor material for a semiconductor substrate used in semiconductor chips. In various embodiment, semiconductor substrate 2 includes one or more semiconductor devices, such as transistors, isolation trenches, contacts, and the like not specifically depicted in FIG. 1. In some embodiments, bottom electrode 10 resides on a semiconductor device or a contact to a semiconductor device residing in semiconductor substrate 2. In other embodiments, BE 10 is a portion of a conductive layer of a semiconductor device and may be a line, a via pad, a contact, or other conductive feature of the semiconductor structure. BE 10 may be in or on a portion of a middle-of-line (MOL) semiconductor layer or a back-end-of line (BEOL) interconnect wiring layer.

BE 10 is formed with known semiconductor processes for semiconductor device electrode formation. For example, after forming an opening in dielectric 3, BE10 may be formed by a deposition of a conductive metallic material into the opening in dielectric 3. For example, the conductive material forming BE 10 may include, but is not limited to, copper (Cu), titanium nitride (TiN), tungsten (W), tungsten nitride (WN), tungsten carbide (WC), silver (Ag), gold (Au), aluminum (Al) or multilayered stacks thereof. The conductive metallic material may be formed by a deposition process such as, for example, chemical vapor deposition (CVD), physical vapor deposition (PVD), plasma enhanced CVD (PECVD), sputtering, atomic layer deposition (ALD) or plating. A planarization process or an etch back process may follow the deposition of the conductive metallic material that provides the bottom electrode 10. In various embodiments, bottom electrode 10 has one of a rectangular shape, a round, oval, or triangular shape.

Dielectric 3 may comprise any suitable insulating/dielectric material that is commonly utilized in semiconductor process technologies including, but not limited to, silicon oxide, silicon nitride, silicon oxynitride, SiCOH, SICH, SiCNH, or other types of silicon based low-k dielectrics (e.g., with a dielectric constant value (k) less than 4.0), porous dielectrics, known ULK (ultra-low-k) dielectric materials (with k less than about 2.5), or any suitable combination of those materials.

FIG. 2 is a cross-sectional view of semiconductor structure 200 after depositing dielectric material 5 and dielectric material 7 over BE 10 and dielectric 3 in accordance with an embodiment of the present invention. As depicted, FIG. 2 includes the elements of FIG. 1 and dielectric material 5 and dielectric material 7.

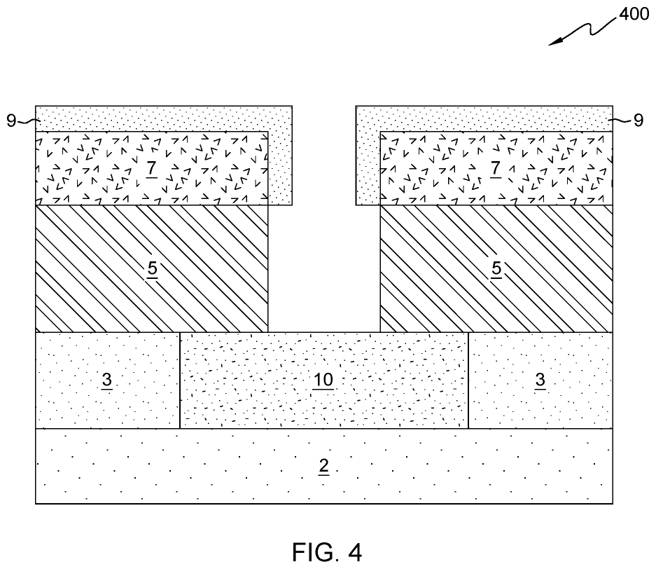

Dielectric material 5 can be deposited on exposed surfaces of BE 10 and dielectric 3 using a known deposition process such as CVD, PVD, and ALD but is not limited to these deposition processes. The thickness of dielectric material 5 after deposition may be in the range of 20 to 50 nm but is not limited to these thicknesses. Dielectric material 5 can be composed of any dielectric material that does not allow a selective dielectric deposition of selective dielectric layer 9 depicted later in FIG. 4. Dielectric material 5, for example, can be composed of Al₂O₃ but is not limited to this material. Using a material like Al₂O₃ for dielectric material 5 can prevent a deposition of selective dielectric layer 9 on the exposed surfaces of dielectric material 5 as depicted later in FIG. 4. In various embodiments, dielectric material 5 and dielectric material 7 are selected to have a different selective deposition of a third dielectric material (e.g., SiN). For example, dielectric material 5 does not allow a deposition of the third dielectric material, such as SiN on exposed surfaces.

Dielectric material 7 can be deposited on the exposed surface of dielectric material 5 using a known deposition process such as CVD, PVD, ALD, etc. The thickness of dielectric material 7 after deposition may be in the range of 10 to 30 nm but is not limited to these thicknesses. Dielectric material 7 can be composed of any dielectric material that allows a selective dielectric deposition of selective dielectric layer 9 depicted later in FIG. 4. Dielectric material 7, for example, can be composed of SiN when dielectric material 5 is composed of Al₂O₃ but is not limited to this material. Using a material like SiN allows a deposition of selective dielectric layer 9 on the exposed surfaces of dielectric material 7 as depicted later in FIG. 4.

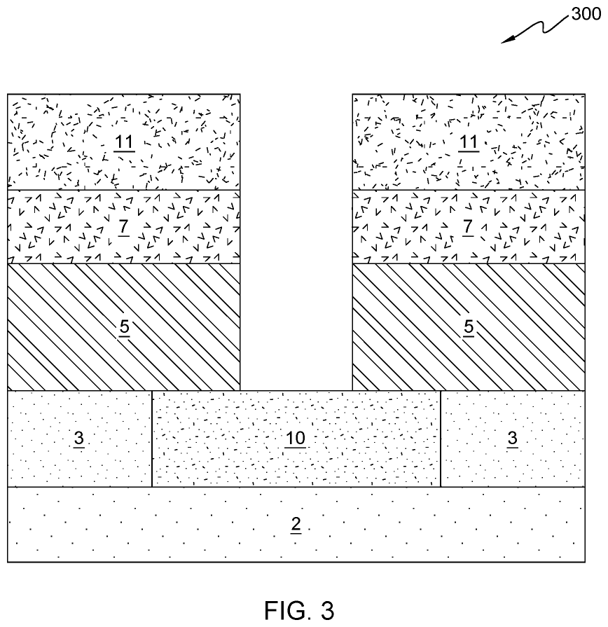

FIG. 3 is a cross-sectional view of semiconductor structure 300 after patterning mask 11 to form a via hole through dielectric material 5 and dielectric material 7 in accordance with an embodiment of the present invention. As depicted, FIG. 3 includes mask 11, dielectric material 5, dielectric material 7, BE 10, dielectric 3 around BE 10, and substrate 2. Mask 11 can be any mask material for patterning a semiconductor structure that is deposited by known deposition methods (e.g., spin coating, etc.). Mask 11 is patterned and a portion of dielectric material 7 and dielectric material 5 not covered by mask 11 are removed, for example, by a wet or dry etching process. After removing dielectric material 5 and 7 a portion of BE 10 is exposed. After removing the portions of dielectric material 7 and dielectric material 5, a hole or pore with a diameter in the range of 15 to 30 nm formed but the hole diameter is not limited to this range.

FIG. 4 is a cross-sectional view of semiconductor structure 400 after selectively depositing selective dielectric layer 9 on the exposed surfaces of dielectric material 7 in accordance with an embodiment of the present invention. As depicted, FIG. 4 includes the elements of FIG. 3 and selective dielectric layer 9 on exposed surfaces of dielectric material 7.

Using a known conformal deposition process such as ALD, for example, selective dielectric layer 9 deposits on dielectric material 7 but not on the exposed surfaces of dielectric material 5. As depicted, selective dielectric layer 9 does not pinch off the opening in dielectric material 7. Selective dielectric layer 9 on dielectric material 7 covers the top portion of the via etched in FIG. 3. In various embodiments, selective dielectric layer 9 is composed of Si₂O₃ or SiN. In other embodiments, selective dielectric layer 9 is composed of any dielectric material capable of depositing on dielectric material 5 but does not deposit on dielectric material 5. A thickness of selective dielectric layer 9 is in the range of 5 to 10 nm but is not limited to these thicknesses. After the deposition of selective dielectric layer 9, the recess or via hole has a bottle-like shape. The shape of the recess after selective dielectric layer 9 deposition includes a wider opening directly adjacent to dielectric material 5 and a narrower opening directly adjacent to selective dielectric layer 9 that is on vertical surfaces of dielectric material 7.

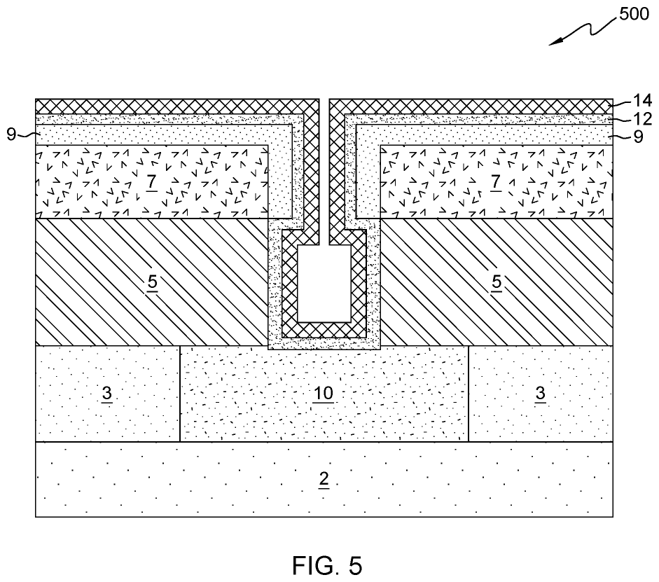

FIG. 5 is a cross-sectional view of semiconductor structure 500 after forming a heater element by conformally depositing a first heater material 12 over the semiconductor structure and conformally depositing second heater material 14 over first heater material 12 in accordance with an embodiment of the present invention. As depicted, FIG. 5 includes the elements of FIG. 4 with first heater material 12 and second material 14. As depicted, the heater element formed in FIG. 5 is a multilayer heater element. The heater conductor can be made of a single material (e.g., TiN) or multiple-layered materials (e.g., TaN/TiN/TaN). Other suitable, conductive materials are also contemplated. Other heater conductor materials include hafnium nitride (HfN), niobium nitride (NbN), WN, tungsten carbon nitride (WCN), or other material commonly used in heater elements in a phase change memory cell can be deposited in FIG. 5.

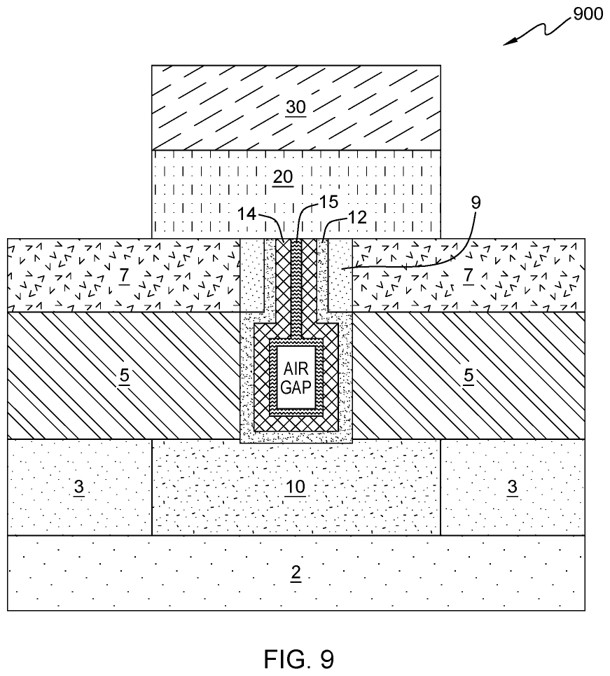

First heater material 12 is conformally deposited, for example, using ALD, over the exposed surfaces of selective dielectric layer 9, dielectric material 5, and BE 10. In various embodiments, first heater material 12 is composed of a material providing good thermal insulation, such as, tantalum nitride (TaN). The thickness of first dielectric material 12 is in the range of 2 to 6 nm. Second dielectric material 14 can also be conformally deposited on first heater material 12, for example, using ALD. As depicted in FIG. 4, the deposition of first heater material 12 and second heater material 14 does not pinch off the via created by the opening in selective dielectric layer 9 and dielectric material 5. The thickness of second dielectric material 14 is in the range of 3 to 6 nm but may be a different thickness in other examples. By depositing a thin layer of second heater material 14, the contact area of second heater material 14 (e.g., TiN) with the phase change material deposited later in FIG. 9 is reduced. By reducing the contact area of second heater material 14 with the phase change material, the programming voltage of the PCM cell is reduced. First heater material 12 and second heater material 14 form a bi-layer heater with a combined thickness in the range of 5 to 12 nm around selective dielectric layer 9 and dielectric material 5 but is not limited to this thickness.

The depositing of first heater material 12 and second heater material 14 does not pinch off or close the opening or recess in dielectric material 7 and dielectric material 5. As depicted in FIG. 4, the opening between the sides of second heater material 14 is narrower adjacent to selective dielectric layer 9 on dielectric material 7 than the opening under selective dielectric layer 9 (e.g., adjacent to or inside of dielectric material 5). The opening created by second heater material 14 over first heater material 12 is wider where first heater material 12 resides on dielectric material 5. For example, the opening or recess surrounded by second heater material 14 may be ten to fifty percent wider adjacent to dielectric material 5 than adjacent to dielectric material 7. The additional width of the opening of second heater material 14 adjacent to dielectric material 5 is not limited to these percentages. In other words, the top portion of the opening or via in dielectric material 5 and 7 with selective dielectric layer 9 on dielectric material 7 is narrower than the bottom portion of the opening surrounded by second heater material 14 and first heater material 12 that are on dielectric material 5.

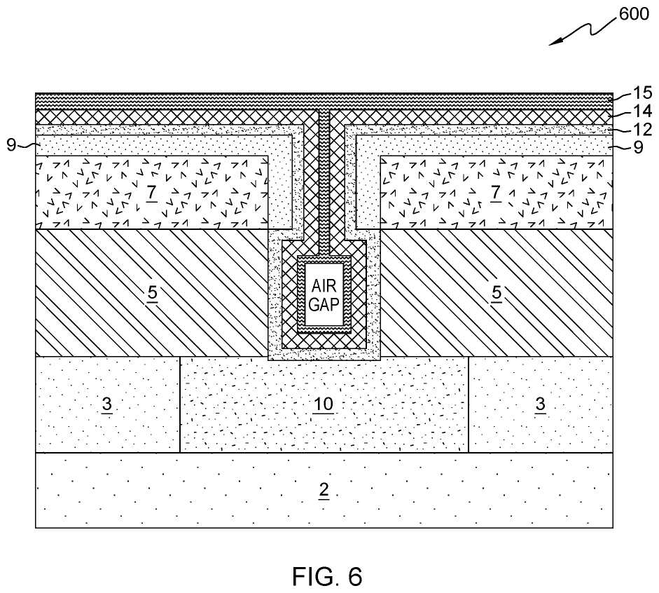

FIG. 6 is a cross-sectional view of semiconductor structure 600 after conformally depositing resistive dielectric material 15 to pinch off the via hole in accordance with an embodiment of the present invention. As depicted, FIG. 6 includes resistive dielectric material 15 with an air gap in the central portion of the via hole or recess adjacent to dielectric material 5. The air gap is surrounded by resistive dielectric material 15 over second dielectric material 14 and first dielectric material 12 where first dielectric material 12 resides on the sidewall of dielectric material 5.

Resistive dielectric material 15 can be conformally deposited by ALD. In various embodiments, resistive dielectric material 15 pinches off or closes the top portion of the opening surrounded by second heater material 14 depicted in FIG. 5. As depicted in FIG. 6, the portions of resistive dielectric material 15 within second heater material 14 above dielectric material 7 and adjacent to the top portion of dielectric material 5 fill the opening between opposing sides of second heater material 14. In various embodiments, resistive dielectric material 15 located in a central area between the two portions of dielectric material 5 creates an opening or air gap depicted in the center of FIG. 6. In an embodiment, the air gap is not present and the recess or via hole is filled and pinched off by resistive dielectric material 15. Resistive dielectric material 15 may be composed of TaN or SiN in various embodiments. In some embodiments, resistive dielectric material 15 can have a low thermal conductivity and a high thermal boundary resistance (G) with respect to the PCM material that is deposited in a later process step. In some embodiments, one or more layers of a resistive material (e.g., the same or different resistive dielectric material) are deposited. The number of layers of resistive dielectric material may vary based, at least in part, on the diameter or size of the opening in dielectric material 5 and dielectric material 7 after heater material depositions.

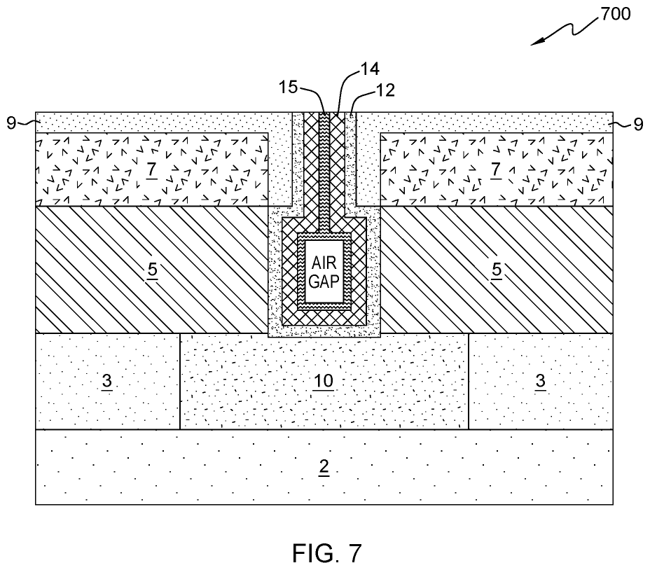

FIG. 7 is a cross-sectional view of semiconductor structure 700 after a chemical mechanical polish (CMP) removes horizontal portions of resistive dielectric material 15, second heater material 14, and first heater material 12 over the surface of selective dielectric layer 9 in accordance with an embodiment of the present invention. As depicted, FIG. 7 includes the elements of FIG. 6 with a top surface of semiconductor structure 700 composed of a horizontal portion of selective dielectric layer 9, exposed top surfaces of first heater material 12, second heater material 14, and resistive dielectric material 15. After the CMP, the bottle-shaped recess is filled in the narrower top portion of the recess with the conformally deposited layers of first heater material 12, second heater material 14, and resistive dielectric material 15. In various embodiments, after the CMP, the bottom portion of the bottle-shaped recess is lined with the conformally deposited layers of first heater material 12, second heater material 14, and resistive dielectric material 15 where an air gap may be present inside a center portion of the bottom portion of the recess directly adjacent to portions of resistive dielectric material 15 on the vertical sidewalls of second dielectric material 14. In some cases, the air gap in the center of the bottom portion of the recess may not be present if the conformal deposition of resistive dielectric material 15 pinches off the recess. In other examples, the bottom portion of recess and the air gap may be wider or larger than depicted in FIG. 7.

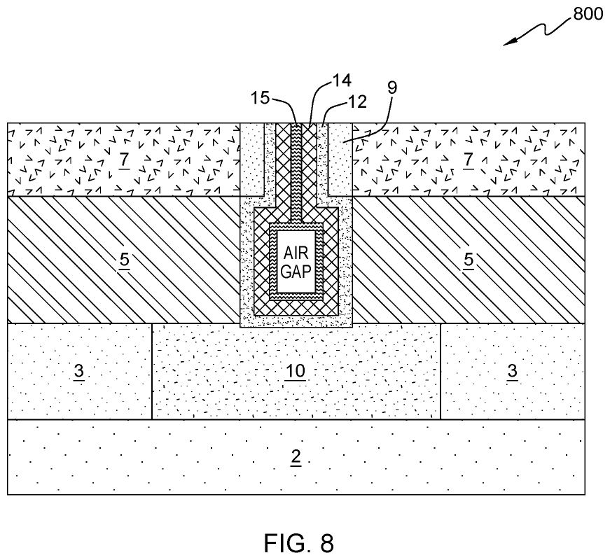

FIG. 8 is a cross-sectional view of semiconductor structure 800 after an optional CMP removes horizontal portions of selective dielectric layer 9 over dielectric material 7 in accordance with an embodiment of the present invention. As depicted, FIG. 8 includes the elements of FIG. 7 without horizontal portions of selective dielectric layer 9. In some embodiments, the horizontal portions of selective dielectric layer 9 are removed at the same time as the horizontal portions of resistive dielectric material 15, second heater material 14, and first heater material 12. The top surface of semiconductor structure 800 after the CMP is composed of a horizontal portion of dielectric material 7, portions of first heater material 12, second heater material 14, and resistive dielectric material 15.

FIG. 9 is a cross-sectional view of semiconductor structure 900 after depositing a layer of phase change material 20 over the top surface of semiconductor structure 800, depositing a layer of top electrode material 30 over phase change material 20, and etching phase change material 20 and top electrode material 30 in accordance with an embodiment of the present invention. As depicted, FIG. 900 includes a top electrode composed of top electrode material 30, phase change material 20 under top electrode material 30 where phase change material 20 resides on a portion of dielectric material 7, exposed top surfaces of first heater material 12, second heater material 14, and resistive dielectric material 15. Semiconductor structure 900 is formed on semiconductor structure 800 after the CMP removes the portion of selective dielectric layer 9 on dielectric material 7.

A layer of phase change material 20 may be deposited over the exposed surfaces of dielectric material 7, first heater material 12, second heater material 14, and resistive dielectric material 15. First heater material 12 and second heater 14 form a ring around resistive dielectric material 15. Deposition of phase change material 20 can occur with known semiconductor deposition processes (e.g., PVD, CVD, spin-on processes), and thickness of phase change material 20 deposition can range from 50 to 200 nm but is not limited to these thicknesses. Phase change material 20 may be any known phase change material. In various embodiments, phase change material 20 is a chalcogenide or chalcogenide glass material. In some embodiments, phase change material 20 is compose of GST (i.e., germanium (Ge), antimony (Sb), tellurium (Te)). For example, phase change material 20 can be a doped or undoped GST, such as, Ge₂Sb₂Te₅. Alternatively, other suitable materials for phase-change material 20 can include Si—Sb—Te (silicon-antimony-tellurium) alloys, Ga—Sb—Te (gallium-antimony-tellurium) alloys, Ge—Bi—Te (germanium-bismuth-tellurium) alloys, In—Se (indium-tellurium) alloys, As—Sb—Te (arsenic-antimony-tellurium) alloys, Ag—In—Sb—Te (silver indium-antimony-tellurium) alloys, Ge—In—Sb—Te alloys, Ge—Sb alloys, Sb—Te alloys, Si—Sb alloys, Ge—Te alloys combinations thereof, or other phase-change material suitable for use in a PCM device. Phase change material 20 may be undoped or doped with one or more of O, N, H, SiO₂, SiN, Ti, TixOy, for example. In other embodiments, phase change material 20 may be a reverse phase change material such as Cr₂Ge₂Te₆. A reverse phase change material (e.g., CrGT) is a phase change material with higher resistivity in the crystalline phase than in the amorphous phase. Reverse phase change materials are different from conventional phase change materials in that a reverse phase change material has an inverse resistance change between a low-resistance amorphous phase and a high-resistance crystalline phase. In other words, a reverse phase change material, such as, CrGT have a low resistivity in the amorphous state compared to a conventional phase change material with a high resistance in the amorphous state. Additionally, CrGT as a reverse phase change material exhibits an ultralow operation energy for amorphization.

Phase change material 20 directly contacts a top surface of first heater material 12 and second heater material 14. The contact area of first heater material 12 and second heater material 14 with phase change material 20 forms a ring of first heater material 12 and second heater material 14 (e.g., the bi-layer heater) where the thickness of the ring is about 5 to 12 nm with an outside diameter that is about 15 to 30 nm but is not limited to these diamensions.

Top electrode material 30 deposition can occur using any known electrode material deposition processes, such as CVD, PVD, PECVD, sputtering, ALD, or plating. Top electrode material 30 can be any known electrode material and may be the same material as BE 10 or a different material than BE 10. For example, top electrode material 30 may be composed of, but is not limited to, copper (Cu), titanium nitride (TiN), tungsten (W), tungsten nitride (WN), tungsten carbide (WC), silver (Ag), gold (Au), aluminum (Al) or multilayered stacks thereof. A planarization process may occur after the deposition of top electrode material 30. Using known photolithographic processes and a wet or dry etching process such as RIE, top electrode material 30 may be patterned and both top electrode material 30 and phase change material 20 can be etched. Semiconductor structure 900 with the remaining portion of phase change material 20 under top electrode material 30 and on selective dielectric layer 9, first heater material 12, second heater material 14, resistive dielectric material 15, and a portion of the top surface of dielectric material 7 forms a phase change memory cell. As known to one skilled in the art, the stack of top electrode material 30 and phase change material 20 long with the exposed top surface of dielectric material 7 may be covered with one or more dielectric materials or interlayer dielectric materials (not depicted in FIG. 9) and top electrode material 30 may connect by a contact or via with other semiconductor layers or devices formed in later semiconductor processes.

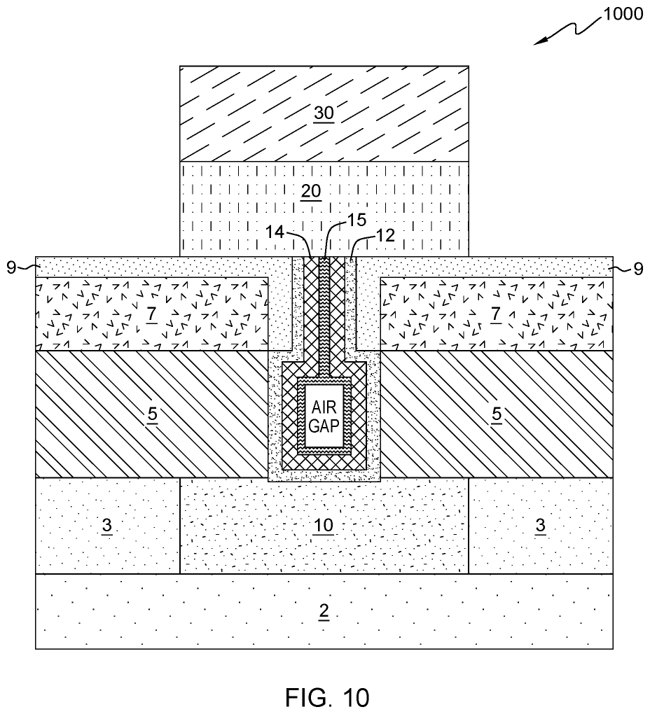

FIG. 10 is a cross-sectional view of semiconductor structure 1000 after depositing a layer of phase change material 20 over the top surface of semiconductor structure 700, depositing a layer of top electrode material 30 over phase change material 20, and etching top electrode material 30 and phase change material 20 in accordance with an embodiment of the present invention. As depicted, FIG. 10 includes a top electrode formed from top electrode material 30 over a remaining portion of phase change material 20 where phase change material 20 resides on a horizontal portion of selective dielectric layer 9. exposed top surfaces of first heater material 12, second heater material 14, and resistive dielectric material 15 with dielectric material 7, dielectric material 5, BE 10, dielectric 3, and substrate 2. Semiconductor structure 1000 can be formed on semiconductor structure 700 after the CMP of semiconductor structure. Semiconductor structure 1000 and semiconductor structure 900 are each one of two different embodiments of the present invention.

Semiconductor structure 1000 may be formed with the processes discussed above with respect to FIG. 7 and FIGS. 1-6. As previously discussed with respect to FIG. 9, top electrode material 30 may connect to other semiconductor lines, contacts, and/or via. Semiconductor structure 1000 may be covered, at least in part, by one or more dielectric materials in additional steps (not depicted). Semiconductor structure 1000 can be a phase change memory cell or a phase change memory device that provides a reduced heater surface area with the phase change material 20 to reduce the forming voltage or reset current needed for the phase change memory cell device switching. Additionally, semiconductor structure 1000 like semiconductor structure 900 provides a bi-layer heater composed of first heater material 12 and second heater material 14 that has a narrower width in the top portion of the bi-layer heater contacting phase change material 20. The ring of first heater material 12 and second heater material 14 provides a smaller heater contact area with phase change material 20 than conventional heater designs. Additionally, semiconductor structure 1000 like semiconductor structure 900 can provide an air gap in the center of the lower portion of the bi-layer heater composed of the conformally deposited layers of first heater material 12 and second heater material 14 where the air gap minimizes heat loss in the bottom portion of the heater. Minimizing heat loss in the bottom portion of the bi-layer heater depicted in FIG. 10 improves the amount of heat provided to switch the state of phase change material 20 (i.e., allows a lower reset current to switch phase change material 20).

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A phase change memory cell comprising:
a phase change material contacting a narrower top portion of a bi-layer heater;
the bi-layer heater with a wider bottom portion of the bi-layer heater contacting a first electrode; and
a first dielectric material directly inside the bi-layer heater and surrounding an air gap in a lower portion of the first dielectric material.

2. The phase change memory cell of claim 1, further comprising:
a second electrode contacting the phase change material;
a second dielectric material on a portion of the first electrode and contacting the wider bottom portion of the bi-layer heater; and
a third dielectric on the second dielectric material directly contacts a sidewall of a fourth dielectric material, wherein the fourth dielectric material directly contacts the narrower top portion of the bi-layer heater.

3. The phase change memory cell of claim 2, wherein the fourth dielectric material is above a top portion of the wider bottom portion of the bi-layer heater.

4. The phase change memory cell of claim 2, wherein the narrower top portion of the bi-layer heater is between the first dielectric material and the fourth dielectric material, and wherein a top surface of the narrow top portion of the bi-layer heater directly contacts a portion of the phase change material.

5. The phase change memory cell of claim 2, wherein the phase change material is over a portion of the third dielectric material, the fourth dielectric material, the narrower top portion of the bi-layer heater, and the first dielectric material.

6. The phase change memory cell of claim 1, wherein the narrower top portion of the bi-layer heater provides a ring of contact area with the phase change material.

7. The phase change memory cell of claim 2, wherein the bi-layer heater includes a first heater material contacting the first electrode, the third dielectric material, the fourth dielectric material, the phase change material, and a second heater material, wherein the second heater material is inside the first heater material and additionally contacting the first dielectric material and the phase change material.

8. The phase change memory cell of claim 2, wherein the bi-layer heater is between (i) the first dielectric material and (ii) a sidewall of the second dielectric material, a sidewall of the fourth dielectric material, and the first electrode.

9. The phase change memory cell of claim 1, wherein the air gap is adjacent to the wider bottom portion of the bi-layer heater.

10. A phase change memory cell comprising:
a first dielectric material inside a bi-layer heater, wherein the first dielectric material surrounds an air gap adjacent to a wider bottom portion of the bi-layer heater;
a first surface of a phase change material contacting a top electrode; and
a second surface of the phase change material contacting the first dielectric material, the bi-layer heater, and a second dielectric material.

11. The phase change memory cell of claim 10, further comprising:
a bottom electrode contacting the bi-layer heater;
a third dielectric material contacting the wider portion of the bi-layer heater; and
a fourth dielectric contacting the first dielectric and is over the third dielectric material.

12. The phase change memory cell of claim 10, wherein the bi-layer heater includes a narrower top portion and the wider bottom portion.

13. The phase change memory cell of claim 12, wherein the narrower top portion of the bi-layer heater is surrounded by the second dielectric material.

14. The phase change memory cell of claim 11, wherein wherein the bi-layer heater includes a first heater material contacting the first electrode, the third dielectric material, the fourth dielectric material, the phase change material, and a second heater material, wherein the second heater material is inside the first heater material and additionally contacting the first dielectric material and the phase change material.

15. A method of forming a phase change memory cell comprising:
depositing a layer of a first dielectric material over a bottom electrode in an interlayer dielectric material;
depositing a layer of a second dielectric material over the first dielectric material;
patterning a mask material;
etching a via hole in the first dielectric material and the second dielectric material;
selectively depositing a layer of a third dielectric material on exposed surfaces of the second dielectric material;
conformally depositing a first heater material on exposed surfaces of the bottom electrode, the first dielectric material, and the third dielectric material;
conformally depositing a second heater material on the first heater material;
conformally depositing a fifth dielectric material on the second heater material;
performing a chemical-mechanical polish to remove horizontal portions of the third dielectric material, the second heater material, the first heater material, and the fifth dielectric material;
depositing a layer of a phase change material;
depositing a layer of electrode material over the phase change material; and
patterning and etching portions of the phase change material and the electrode material to form the phase change memory cell.

16. The phase change memory cell of claim 15, wherein depositing the fifth dielectric material on the second heater material pinches off a top portion of the via adjacent to the second heater material.

17. The phase change memory cell of claim 16, further comprises forming an air gap inside a bottom portion of the second heater material.

18. The phase change memory cell of claim 15, wherein the second dielectric material is a material that does not conformally coat the first dielectric material.

19. The phase change memory cell of claim 15, wherein the second dielectric material narrows a top portion of the via hole.

20. The phase change memory cell of claim 15, wherein the first heater material and the second heater material form a bi-layer heater contacting a portion of the phase change material, wherein a bottom portion of the bi-layer heater includes an air gap adjacent to the second heater material.
